(19) United States
(12) Patent Application Publication
(10) Pub. No.: US 2008/0137471 A1
(43) Pub. Date: Jun. 12, 2008

(54) Memory with clock distribution options

(76) Inventors: Josef Schnell, Charlotte, VT (US); Farrukh Aquil, S. Burglington, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/635,189

(22) Filed: Dec. 7, 2006

(51) Int. Cl. G11C 7/22

(52) U.S. Cl. 365/233.11

(57) ABSTRACT

One embodiment provides a memory including a first receiver, a second receiver, a circuit, a first buffer, and a second buffer. The first receiver is situated on one side of the memory and configured to receive a first clock signal and provide a first clock tree signal. The second receiver is situated on another side of the memory and configured to receive a second clock signal and provide a second clock tree signal. The circuit is configured to receive the first clock tree signal and provide a distributed clock signal. The first buffer is configured to selectively provide one of the first clock tree signal and the distributed clock signal to the one side of the memory and the second buffer is configured to selectively provide one of the second clock tree signal and the distributed clock signal to the other side of the memory.

### BACKGROUND

Typically, a computer system includes a number of integrated circuit chips that communicate with one another to perform system applications. As chip speeds increase, the amount of data communicated between chips increases to meet the demands of some system applications. Often, the computer system includes a controller, such as a micro-processor, and one or more memory chips, such as random access memory (RAM) chips. The controller communicates with the memory to store data and to read the stored data.

The RAM chips can be any suitable type of RAM, such as dynamic RAM (DRAM) including single data rate synchronous DRAM (SDR-SDRAM), double data rate SDRAM (DDR-SDRAM), graphics DDR-SDRAM (GDDR-SDRAM), low power SDR-SDRAM (LPSDR-SDRAM), and low power DDR-SDRAM (LPDDR-SDRAM). Also, the DRAM can be any suitable generation of DRAM, including double data rate two SDRAM (DDR2-SDRAM) and higher generation DRAM circuits. Usually, each new generation of DRAM operates at an increased data rate from the previous generation.

DRAM chips receive a clock signal to operate. Some DRAM chips receive the clock signal at a pad along the edge of the DRAM chip, referred to as an edge pad, and some DRAM chips receive the clock signal at a pad centrally located on the DRAM chip, referred to as a center pad. Customers choose DRAM based on DRAM type, footprint, data rate, and the size needed for their applications. Fluctuating customer demands make it difficult to predict which type, footprint, data rate, and size will result in the largest profit to the manufacturer.

Often, the speed performance, referred to as the AC performance, of the DRAM chip is determined by the clock signal paths. In an edge pad architecture having one clock pad and one clock receiver situated on one side of the chip and data input/output pads (DQ's) situated on opposite sides of the chip, the AC performance of the DRAM is reduced by the resistive and capacitive (RC) components of the clock path.

For these and other reasons there is a need for the present invention.

### SUMMARY

The present disclosure describes a memory configured to provide either separate clock signals for each side of the memory or a single distributed clock signal for both sides of the memory. One embodiment provides a memory including a first receiver, a second receiver, a circuit, a first buffer, and a second buffer. The first receiver is situated on one side of the memory and configured to receive a first clock signal and provide a first clock tree signal. The second receiver is situated on another side of the memory and configured to receive a second clock signal and provide a second clock tree signal. The circuit is configured to receive the first clock tree signal and provide a distributed clock signal. The first buffer is configured to selectively provide one of the first clock tree signal and the distributed clock signal to the one side of the memory and the second buffer is configured to selectively provide one of the second clock tree signal and the distributed clock signal to the other side of the memory.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a packaged integrated circuit according to the present invention.

FIG. 2 is a diagram illustrating one embodiment of an integrated circuit memory.

FIG. 3 is a diagram illustrating one embodiment of a distributed clock signal circuit.

FIG. 4 is a diagram illustrating one embodiment of the upper right portion of a memory.

FIG. 5 is a diagram illustrating one embodiment of an upper right buffer circuit.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “left,” “right,” “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

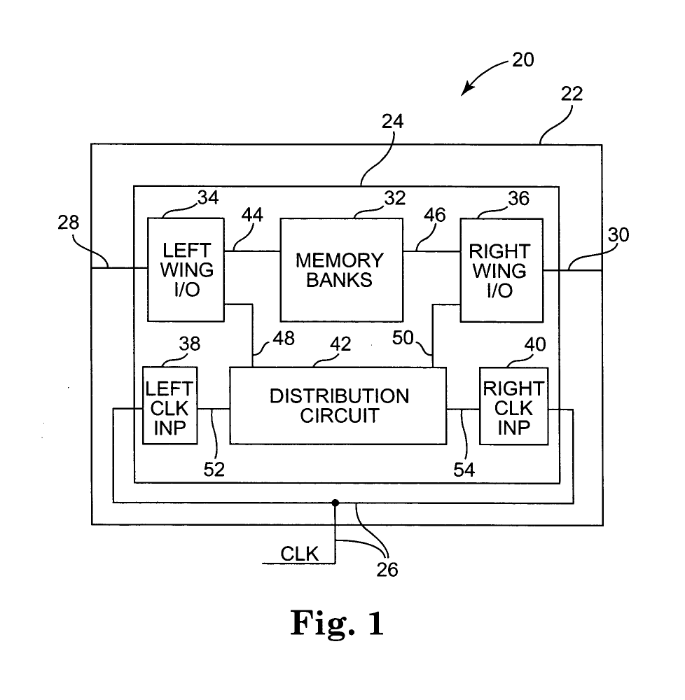

FIG. 1 is a block diagram illustrating one embodiment of a packaged integrated circuit 20, according to the present invention. Packaged integrated circuit 20 includes a package 22 and an integrated circuit memory 24. Memory 24 is a RAM. In one embodiment, memory 24 is a DRAM, such as an SDR-SDRAM or a DDR-SDRAM. In one embodiment, memory 24 is a low power DRAM, such as a LPSDR-SDRAM or a LPDDR-SDRAM. In one embodiment, memory 24 is configured to provide either a LPSDR-SDRAM or a LPDDR-SDRAM. In other embodiments, memory 24 can be any suitable memory or combination of memory types.

Package 22 is electrically coupled to memory 24 via clock path 26, left side input/output (I/O) paths 28, and right side I/O paths 30. An external circuit, such as a controller, transfers data to and from memory 24 via left side I/O paths 28 and right side I/O paths 30. Packaged integrated circuit 20 receives clock signal CLK at 26 and package 22 provides clock signal CLK at 26 to the left side and the right side of memory 24 via clock signal path 26. In other embodiments, package 22 provides clock signal CLK to only one side of memory 24.

Memory 24 receives clock signal CLK at 26 and provides clock signals to the left side and the right side of memory 24 to output signals via left side I/O paths 28 and right side I/O paths 30. Memory 24 can be set to provide either one of two clock signal distribution options. In one option, a clock signal received on the left side is used to output data via left side I/O paths 28 and the clock signal received on the right side is used to output data via right side I/O paths 30. Outputting signals on each side of memory 24 via clock signals received on the same side, improves the AC performance of memory 24. In the other option, a single clock signal based on a clock signal received on only one side of memory 24 is distributed in memory 24 to output data via both left side I/O paths 28 and right side I/O paths 30. In one embodiment, memory 24 is set to provide one of the options via metal masks. In one embodiment, memory 24 is set to provide one of the options via fuses.

Memory 24 includes memory banks 32, a left wing I/O circuit 34, a right wing I/O circuit 36, a left clock input circuit 38, a right clock input circuit 40, and a clock signal distribution circuit 42. Memory banks 32 are electrically coupled to left wing I/O circuit 34 via left data paths 44 and to right wing I/O circuit 36 via right data paths 46. Distribution circuit 42 is electrically coupled to left wing I/O circuit 34 via left clock signal paths 48 and to right wing I/O circuit 36 via right clock signal paths 50. Also, distribution circuit 42 is electrically coupled to left clock input circuit 38 via left clock tree path 52 and to right clock input circuit 40 via right clock tree path 54.

Memory 24 includes multiple memory banks 32. Each of the multiple memory banks 32 includes RAM memory cells, which store data in memory 24. The RAM memory cells correspond to the memory type of memory 24. In one embodiment, the RAM memory cells are DRAM memory cells in a DRAM, such as an SDR-SDRAM, a DDR-SDRAM, a LPSDR-SDRAM, and/or a LPDDR-SDRAM. In one embodiment, the RAM memory cells are in one or more arrays of RAM memory cells. In one embodiment, memory 24 includes four memory banks. In other embodiments, memory 24 includes any suitable number of memory banks.

Left wing I/O circuit 34 receives write data from an external circuit via left side I/O paths 28 and provides the received write data to memory banks 32 for storage via left data paths 44. Left wing I/O circuit 34 receives a clock signal from distribution circuit 42 via left clock signal paths 48 and read data from memory banks 32 via left data paths 44. Left wing I/O circuit 34 provides the read data to the external circuit via left side I/O paths 28.

Right wing I/O circuit 36 receives write data from an external circuit via right side I/O paths 30 and provides the received write data to memory banks 32 for storage via right data paths 46. Right wing I/O circuit 36 receives a clock signal from distribution circuit 42 via right clock signal paths 50 and read data from memory banks 32 via right data paths 46. Right wing I/O circuit 36 provides the read data to the external circuit via right side I/O paths 30.

In one option, left clock input circuit 38 receives clock signal CLK at 26 and provides a left clock tree signal to distribution circuit 42 via left clock tree path 52 and right clock input circuit 40 receives clock signal CLK at 26 and provides a right clock tree signal to distribution circuit 42 via right clock tree path 54. In another option, left clock input circuit 38 is disabled or powered down and right clock input circuit 40 receives clock signal CLK at 26 and provides a right clock tree signal to distribution circuit 42 via right clock tree path 54. In another embodiment, the left clock input circuit 38 is not powered down in either option.

Distribution circuit 42 receives the left clock tree signal and the right clock tree signal and provides a distributed clock signal that is based on the right clock tree signal. The distributed clock signal is buffered to provide the distributed clock signal to the left side and right side of memory 24. Distribution circuit 42 selects either the left clock tree signal or the distributed clock signal and provides the selected signal to left wing I/O circuit 34 via left clock signal paths 48. Distribution circuit 42 selects either the right clock tree signal or the distributed clock signal and provides the selected signal to right wing I/O circuit 36 via right clock signal paths 50. In another embodiment, distribution circuit 42 receives the left clock tree signal and the right clock tree signal and provides a distributed clock signal based on the left clock tree signal.

In operation of one option, left clock input circuit 38 and right clock input circuit 40 receive clock signal CLK at 26. Left clock input circuit 38 provides the left clock tree signal to distribution circuit 42 and right clock input circuit 40 provides the right clock tree signal to distribution circuit 42. Distribution circuit 42 receives the left clock tree signal and provides the left clock tree signal to left wing I/O circuit 34. Distribution circuit 42 receives the right clock tree signal and provides the right clock tree signal to right wing I/O circuit 36.

In operation of the other option, right clock input circuit 40 receives clock signal CLK at 26 and provides the right clock tree signal to distribution circuit 42. Left clock input circuit 38 is disabled or powered down to reduce power needs and noise. Distribution circuit 42 provides the distributed clock signal based on the right clock tree signal to left wing I/O circuit 34 and to right wing I/O circuit 36.

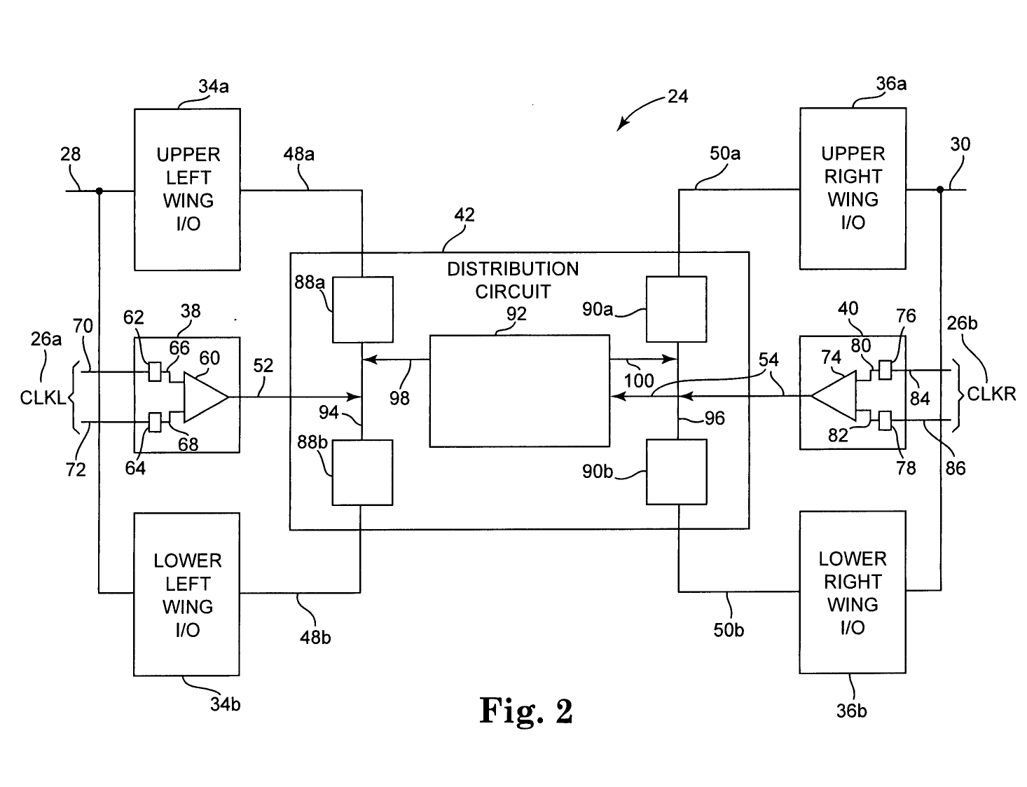

FIG. 2 is a diagram illustrating one embodiment of integrated circuit memory 24. Memory 24 includes an upper left wing I/O circuit 34a, a lower left wing I/O circuit 34b, an upper right wing I/O circuit 36a, a lower right wing I/O circuit 36b, left clock input circuit 38, right clock input circuit 40, and clock signal distribution circuit 42.

Distribution circuit 42 is electrically coupled to upper left wing I/O circuit 34a via upper left clock signal paths 48a and to lower left wing I/O circuit 34b via lower left clock signal paths 48b. Distribution circuit 42 is electrically coupled to upper right wing I/O circuit 36a via upper right clock signal paths 50a and to lower right wing I/O circuit 36b via lower right clock signal paths 50b. Distribution circuit 42 is electrically coupled to left clock input circuit 38 via left clock tree path 52 and to right clock input circuit 40 via right clock tree path 54.

Upper left wing I/O circuit 34a receives write data from an external circuit via left side I/O paths 28 and provides the received write data to memory banks (FIG. 1) for storage. Upper left wing I/O circuit 34a receives a clock signal from distribution circuit 42 via upper left clock signal paths 48a and read data from the memory banks. Upper left wing I/O circuit 34a provides the read data to the external circuit via left side I/O paths 28.

Lower left wing I/O circuit 34b receives write data from an external circuit via left side I/O paths 28 and provides the received write data to memory banks for storage. Lower left wing I/O circuit 34b receives a clock signal from distribution circuit 42 via lower left clock signal paths 48b and read data from the memory banks. Lower left wing I/O circuit 34b provides the read data to the external circuit via left side I/O paths 28.

Upper right wing I/O circuit 36a receives write data from an external circuit via right side I/O paths 30 and provides the received write data to memory banks for storage. Upper right wing I/O circuit 36a receives a clock signal from distribution circuit 42 via upper right clock signal paths 50a and read data from the memory banks. Upper right wing I/O circuit 36a provides the read data to the external circuit via right side I/O paths 30.

Lower right wing I/O circuit 36b receives write data from an external circuit via right side I/O paths 30 and provides the received write data to memory banks for storage. Lower right wing I/O circuit 36b receives a clock signal from distribution circuit 42 via lower right clock signal paths 50b and read data from the memory banks. Lower right wing I/O circuit 36b provides the read data to the external circuit via right side I/O paths 30.

In one clock distribution option, left clock input circuit 38 receives clock signal CLKL at 26a and provides a left clock tree signal to distribution circuit 42 via left clock tree path 52 and right clock input circuit 40 receives clock signal CLKR at 26b and provides a right clock tree signal to distribution circuit 42 via right clock tree path 54. In the other clock distribution option, left clock input circuit 38 is disabled or powered down and right clock input circuit 40 receives clock signal CLKR at 26b and provides a right clock tree signal to distribution circuit 42 via right clock tree path 54. In another embodiment, the left clock input circuit 38 is enabled in both options.

Left clock input circuit 38 includes left wing receiver 60 and input pads 62 and 64. Left wing receiver 60 is electrically coupled to input pad 62 via input path 66 and to input pad 64 via input path 68. Clock signal CLKL at 26a is a differential clock signal, where input pad 62 receives one side of the differential clock signal via clock input path 70 and input pad 64 receives the other side of the differential clock signal via clock input path 72.

Input pads 62 and 64 receive clock signal CLKL at 26a via clock input paths 70 and 72 and provide clock signal CLKL to left wing receiver 60 via input paths 66 and 68. Left wing receiver 60 receives the differential clock signal CLKL and provides the left clock tree signal to distribution circuit 42 via left clock tree path 52. In one clock distribution option left wing receiver 60 is enabled and in the other clock distribution option left wing receiver 60 is disabled or powered down.

Right clock input circuit 40 includes right wing receiver 74 and input pads 76 and 78. Right wing receiver 74 is electrically coupled to input pad 76 via input path 80 and to input pad 78 via input path 82. Clock signal CLKR at 26b is a differential clock signal, where input pad 76 receives one side of the differential clock signal via clock input path 84 and input pad 78 receives the other side of the differential clock signal via clock input path 86.

Input pads 76 and 78 receive clock signal CLKR at 26b via clock input paths 84 and 86 and provide clock signal CLKR to right wing receiver 74 via input paths 80 and 82. Right wing receiver 74 receives the differential clock signal CLKR and provides the right clock tree signal to distribution circuit 42 via right clock tree path 54.

Distribution circuit 42 receives the left clock tree signal at 52 and the right clock tree signal at 54 and provides a distributed clock signal that is based on the right clock tree signal at 54. The distributed clock signal is buffered to provide a left distributed clock signal to the left side of memory 24 and a right distributed clock signal to the right side of memory 24. Distribution circuit 42 selects either the left clock tree signal or the left distributed clock signal and provides the selected signal to upper and lower left wing I/O circuits 34a and 34b via upper and lower left clock signal paths 48a and 48b, respectively. Distribution circuit 42 selects either the right clock tree signal or the right distributed clock signal and provides the selected signal to upper and lower right wing I/O circuits 36a and 36b via upper and lower right clock signal paths 50a and 50b, respectively. In another embodiment, distribution circuit 42 provides a distributed clock signal based on the left clock tree signal at 52.

Distribution circuit 42 includes an upper left buffer circuit 88a, a lower left buffer circuit 88b, an upper right buffer circuit 90a, a lower right buffer circuit 90b, and a distributed clock signal circuit 92. Upper left buffer circuit 88a is electrically coupled to upper left wing I/O circuit 34a via upper left clock signal paths 48a. Lower left buffer circuit 88b is electrically coupled to lower left wing I/O circuit 34b via lower left clock signal paths 48b. Upper right buffer circuit 90a is electrically coupled to upper right wing I/O circuit 36a via upper right clock signal paths 50a. Lower right buffer circuit 90b is electrically coupled to lower right wing I/O circuit 36b via lower right clock signal paths 50b.

Upper left buffer circuit 88a is electrically coupled to lower left buffer circuit 88b via left clock paths 94, and upper right buffer circuit 90a is electrically coupled to lower right buffer circuit 90b via right clock paths 96.

Left wing receiver 60 is electrically coupled to upper left buffer circuit 88a and to lower left buffer circuit 88b via left clock tree path 52 and left clock paths 94. Right wing receiver 74 is electrically coupled to upper right buffer circuit 90a and lower right buffer circuit 90b via right clock tree path 54 and right clock paths 96. Right wing receiver 74 is also electrically coupled to distributed clock signal circuit 92 via right clock tree path 54.

Distributed clock signal circuit 92 is electrically coupled to upper left buffer circuit 88a and to lower left buffer circuit 88b via left distributed signal path 98 and left clock paths 94. Distributed clock signal circuit 92 is electrically coupled to upper right buffer circuit 90a and to lower right buffer circuit 90b via right distributed signal path 100 and right clock paths 96.

Distributed clock signal circuit 92 receives the right clock tree signal at 54 and provides a distributed clock signal that is based on the right clock tree signal at 54. Distributed clock signal circuit 92 provides the left distributed clock signal at 98 to upper left buffer circuit 88a and to lower left buffer circuit 88b via left distributed signal path 98 and left clock paths 94. Distributed clock signal circuit 92 provides the right distributed clock signal at 100 to upper right buffer circuit 90a and to lower right buffer circuit 90b via right distributed signal path 100 and right clock paths 96.

Upper left buffer circuit 88a receives the left clock tree signal at 52 and the left distributed clock signal at 98 and provides either the left clock tree signal at 52 or the left distributed clock signal at 98 to upper left wing I/O circuit 34a via upper left clock signal paths 48a. Lower left buffer circuit 88b receives the left clock tree signal at 52 and the left distributed clock signal at 98 and provides either the left clock tree signal at 52 or the left distributed clock signal at 98 to lower left wing I/O circuits 34b via lower left clock signal paths 48b.

Upper right buffer circuit 90a receives the right clock tree signal at 54 and the right distributed clock signal at 100 and provides either the right clock tree signal at 54 or the right distributed clock signal at 100 to upper right wing I/O circuit 36a via upper right clock signal paths 50a. Lower right buffer circuit 90b receives the right clock tree signal at 54 and the right distributed clock signal at 100 and provides either the right clock tree signal at 54 or the right distributed clock signal at 100 to lower right wing I/O circuit 36b via lower right clock signal paths 50b.

In operation of one clock distribution option, left clock input circuit 38 receives clock signal CLKL at 26a and right clock input circuit 40 receives clock signal CLKR at 26b. Clock signal CLKL at 26a and clock signal CLKR at 26b are based on the same clock signal CLKL. In other embodiments, clock signal CLKL at 26a is based on a different clock signal than clock signal CLKR at 26b.

Input pads 62 and 64 receive differential clock signal CLKL at 26a and provide clock signal CLKL to left wing receiver 60. Input pads 76 and 78 receive differential clock signal CLKR at 26b and provide clock signal CLKR to right wing receiver 74. Left wing receiver 60 receives the differential clock signal CLKL and provides the left clock tree signal to distribution circuit 42. Right wing receiver 74 receives the differential clock signal CLKR and provides the right clock tree signal to distribution circuit 42.

Distributed clock signal circuit 92 receives the right clock tree signal at 54 and provides a distributed clock signal based on the right clock tree signal at 54. Distributed clock signal circuit 92 provides the left distributed clock signal at 98 to upper left buffer circuit 88a and to lower left buffer circuit 88b and distributed clock signal circuit 92 provides the right distributed clock signal at 100 to upper right buffer circuit 90a and to lower right buffer circuit 90b. In other embodiments, distributed clock signal circuit 92 is disabled or powered down to conserve energy in this clock distribution option.

Upper left buffer circuit 88a receives the left clock tree signal at 52 and the left distributed clock signal at 98 and provides the left clock tree signal at 52 to upper left wing I/O circuit 34a. Lower left buffer circuit 88b receives the left clock tree signal at 52 and the left distributed clock signal at 98 and provides the left clock tree signal at 52 to lower left wing I/O circuit 34b.

Upper right buffer circuit 90a receives the right clock tree signal at 54 and the right distributed clock signal at 100 and provides the right clock tree signal at 54 to upper right wing I/O circuit 36a. Lower right buffer circuit 90b receives the right clock tree signal at 54 and the right distributed clock signal at 100 and provides the right clock tree signal at 54 to lower right wing I/O circuit 36b.

In operation of the other option, right clock input circuit 40 receives clock signal CLKR at 26b. Input pads 76 and 78 receive differential clock signal CLKR at 26b and provide clock signal CLKR to right wing receiver 74, which receives the differential clock signal CLKR and provides the right clock tree signal to distribution circuit 42. In one embodiment, left wing receiver 60 is disabled or powered down to conserve energy in this option.

Distributed clock signal circuit 92 receives the right clock tree signal at 54 and provides a distributed clock signal based on the right clock tree signal at 54. Distributed clock signal circuit 92 provides the left distributed clock signal at 98 to upper left buffer circuit 88a and to lower left buffer circuit 88b and distributed clock signal circuit 92 provides the right distributed clock signal at 100 to upper right buffer circuit 90a and to lower right buffer circuit 90b.

Upper left buffer circuit 88a receives the left distributed clock signal at 98 and provides the left distributed clock signal at 98 to upper left wing I/O circuit 34a. Lower left buffer circuit 88b receives the left distributed clock signal at 98 and provides the left distributed clock signal at 98 to lower left wing I/O circuits 34b.

Upper right buffer circuit 90a receives the right clock tree signal at 54 and the right distributed clock signal at 100 and provides the right distributed clock signal at 100 to upper right wing I/O circuit 36a. Lower right buffer circuit 90b receives the right clock tree signal at 54 and the right distributed clock signal at 100 and provides the right distributed clock signal at 100 to lower right wing I/O circuit 36b.

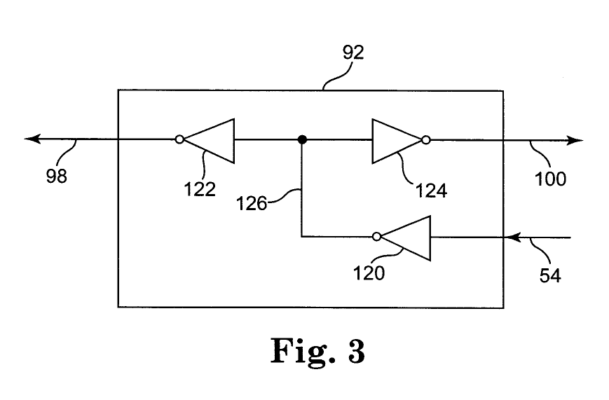

FIG. 3 is a diagram illustrating one embodiment of a distributed clock signal circuit 92, which includes a distribution inverter 120, a left inverter 122, and a right inverter 124. The output of distribution inverter 120 is electrically coupled to the input of left inverter 122 and the input of right inverter 124 via distributed clock signal path 126. In other embodiments, the distribution inverter 120, left inverter 122, and/or right inverter 124 can be different suitable types of buffers, such as non-inverting buffers.

The input of distribution inverter 120 receives the right clock tree signal at 54 and provides the distributed clock signal at 126. The input of left inverter 122 and the input of right inverter 124 receive the distributed clock signal at 126. Left inverter 122 provides the left distributed clock signal at 98 and right inverter 124 provides the right distributed clock signal at 100.

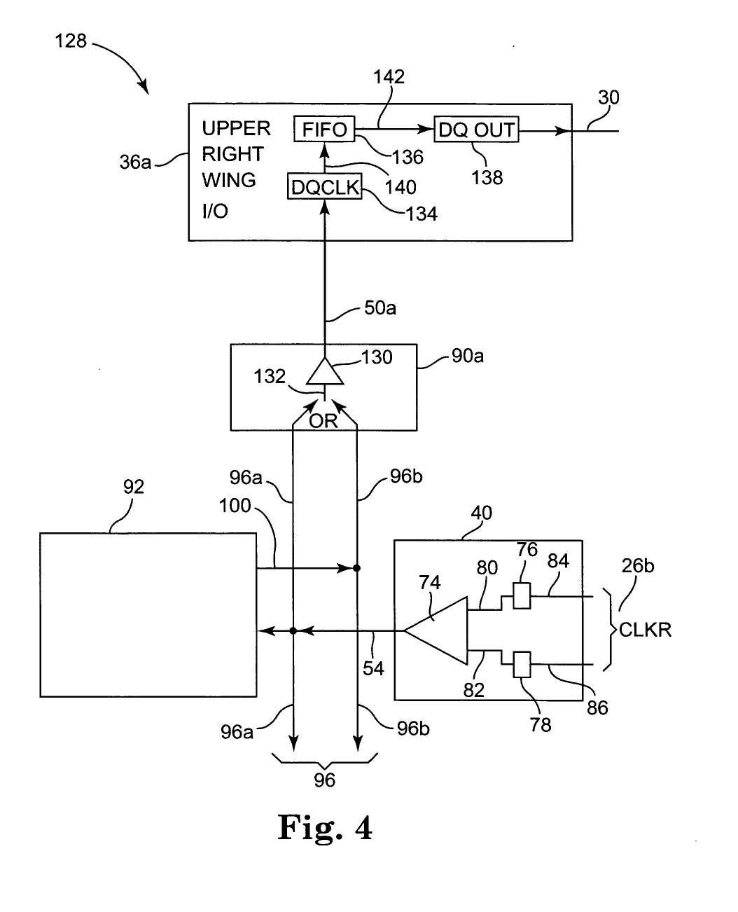

FIG. 4 is a diagram illustrating one embodiment of the upper right portion 128 of memory 24. The upper right portion 128 includes upper right wing I/O circuit 36a, upper right buffer circuit 90a, distributed clock signal circuit 92, and right clock input circuit 40.

Right clock input circuit 40 includes right wing receiver 74 and input pads 76 and 78. Right clock input circuit 40 including the output of right wing receiver 74 is electrically coupled to distributed clock signal circuit 92 via right clock tree path 54. Right clock input circuit 40 including the output of right wing receiver 74 is electrically coupled to upper right buffer circuit 90a via right clock tree path 54 and right clock paths 96a. Distributed clock signal circuit 92 is electrically coupled to upper right buffer circuit 90a via right distributed signal path 100 and right clock paths 96b. Upper right buffer circuit 90a is electrically coupled to upper right wing I/O circuit 36a via upper right clock signal paths 50a.

Right wing receiver 74 is electrically coupled to input pad 76 via input path 80 and to input pad 78 via input path 82. Clock signal CLKR at 26b is a differential clock signal, where input pad 76 receives one side of the differential clock signal via clock input path 84 and input pad 78 receives the other side of the differential clock signal via clock input path 86.

Input pads 76 and 78 receive clock signal CLKR at 26b via clock input paths 84 and 86 and provide clock signal CLKR to right wing receiver 74 via input paths 80 and 82. Right wing receiver 74 receives the differential clock signal CLKR and provides the right clock tree signal to distributed clock signal circuit 92 via right clock tree path 54. Right wing receiver 74 provides the right clock tree signal to upper right buffer circuit 90a via right clock tree path 54 and right clock paths 96a. Distributed clock signal circuit 92 receives the right clock tree signal and provides the right distributed clock signal at 100.

Upper right buffer circuit 90a includes a buffer 130. Input 132 of buffer 130 receives either the right clock tree signal at 54 or the right distributed clock signal at 100. Buffer 130 provides a buffered clock signal at 50a to upper right wing I/O circuit 36a. In one embodiment, buffer 130 is a non-inverting buffer. In other embodiments, buffer 130 is an inverting buffer.

Upper right wing I/O circuit 36a includes a DQ clock circuit 134, a data first-in-first-out (FIFO) circuit 136, and a DQ output circuit 138. Clock circuit 134 is electrically coupled to FIFO circuit 136 via FIFO clock path 140. FIFO circuit 136 is electrically coupled to DQ output circuit 138 via output path 142. Clock circuit 134 receives a clock signal from upper right buffer circuit 90a via upper right clock signal paths 50a and provides a clock signal to FIFO circuit 136 via FIFO clock path 140. Data FIFO circuit 136 receives the clock signal and data and provides data to DQ output circuit 138 via output path 142. DQ output circuit 138 outputs data via right side I/O paths 30.

In operation, right wing receiver 74 receives the differential clock signal CLKR and provides the right clock tree signal to distributed clock signal circuit 92 and upper right buffer circuit 90a. Distributed clock signal circuit 92 receives the right clock tree signal at 54 and provides the right distributed clock signal at 100. In one clock distribution option, input 132 of buffer 130 receives the right clock tree signal and buffer 130 provides the buffered clock signal at 50a based on the right clock tree signal to upper right wing I/O circuit 36a. In the other clock distribution option, input 132 of buffer 130 receives the right distributed clock signal and buffer 130 provides the buffered clock signal at 50a based on the right distributed clock signal to upper right wing PO circuit 36a.

DQ clock circuit 134 receives the buffered clock signal at 50a from upper right buffer circuit 90a and provides a clock signal to FIFO circuit 136. FIFO circuit 136 receives the clock signal and provides data to DQ output circuit 138 via output path 142. DQ output circuit 138 outputs data via right side I/O paths 30.

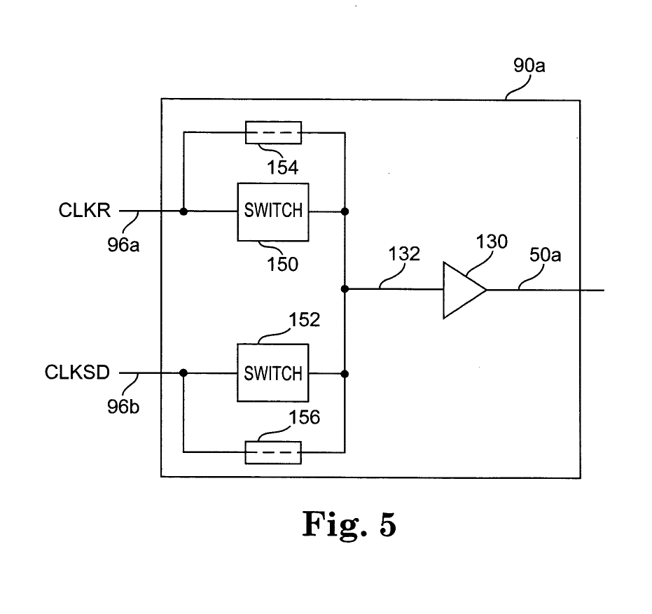

FIG. 5 is a diagram illustrating one embodiment of upper right buffer circuit 90a that receives the right clock tree signal CLKR at 96a and the right distributed clock signal CLKSD at 96b. In one embodiment, each of the clock signals of CLKR at 96a and CLKSD at 96b is a differential signal. In one embodiment, each of the clock signals of CLKR at 96a and CLKSD at 96b is a single, non-differential, signal.

Upper right buffer circuit 90a includes a right clock tree switch 150, a right distributed clock signal switch 152, a right clock tree metal option at 154, and a right distributed clock signal metal option at 156. The outputs of right clock tree switch 150, right distributed clock signal switch 152, right clock tree metal option at 154, and right distributed clock signal metal option at 156 are electrically coupled at input 132 of buffer 130. The inputs of right clock tree switch 150 and the right clock tree metal option at 154 receive the right clock tree signal CLKR at 96a. The inputs of right distributed clock signal switch 152 and the right distributed clock signal metal option at 156 receive the right distributed clock signal CLKSD at 96b. The input 132 of buffer 130 receives either the right clock tree signal or the right distributed clock signal and provides the buffered clock signal at 50a to upper right wing I/O circuit 36a.

The right clock tree switch 150 is activated via an activation mechanism, such as a programmable register or a fuse. If activated, right clock tree switch 150 passes right clock tree signal CLKR at 96a to the input of buffer 130, which uses the right clock tree signal CLKR at 96a to provide the buffered clock signal at 50a to upper right wing I/O circuit 36a.

The right distributed clock signal switch 152 is activated via an activation mechanism, such as a programmable register or a fuse. If activated, right distributed clock signal switch 152 passes right distributed clock signal CLKSD at 96b to the input of buffer 130, which uses the right distributed clock signal CLKSD at 96b to provide the buffered clock signal at 50a to upper right wing I/O circuit 36a.

The right clock tree metal option at 154 can be metalized at processing of memory 24. If metalized, the right clock tree metal option at 154 passes the right clock tree signal CLKR at 96a to the input 132 of buffer 130, which uses the right clock tree signal CLKR at 96a to provide the buffered clock signal at 50a to upper right wing I/O circuit 36a.

The right distributed clock tree metal option at 156 can be metalized at processing of memory 24. If metalized, right distributed clock signal metal option at 156 passes right distributed clock signal CLKSD at 96b to the input 132 of buffer 130, which uses the right distributed clock signal CLKSD at 96b to provide the buffered clock signal at 50a to upper right wing I/O circuit 36a.

In one embodiment, either the right clock tree switch 150 or the right distributed clock signal switch 152 is activated to pass the corresponding clock signal to buffer 130. In another embodiment, either the right clock tree metal option at 154 or the right distributed clock signal metal option at 156 is metalized to pass the corresponding clock signal to buffer 130.

Memory 24 receives a clock signal and provides clock signals to the left side and the right side of memory 24 to output signals via left side I/O paths 28 and right side I/O paths 30. In one option, a clock signal received on the left side is used to output data via left side I/O paths 28 and a clock signal received on the right side is used to output data via right side I/O paths 30. Outputting data signals on each side of memory 24 via corresponding clock signals received on each side of memory 24, improves the AC performance of memory 24. In the other option, a single clock signal based on a clock signal received on only one side of memory 24 is distributed to output data via both left side I/O paths 28 and right side I/O paths 30. This provides flexibility to meet customer needs.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory comprising:
a first receiver situated on one side of the memory and configured to receive a first clock signal and provide a first clock tree signal;
a second receiver situated on another side of the memory and configured to receive a second clock signal and provide a second clock tree signal;
a circuit configured to receive the first clock tree signal and provide a distributed clock signal;
a first buffer configured to selectably provide one of the first clock tree signal and the distributed clock signal to the one side of the memory; and
a second buffer configured to selectably provide one of the second clock tree signal and the distributed clock signal to the other side of the memory.

2. The memory of claim 1, wherein the first buffer provides the first clock tree signal to the one side of the memory and the second buffer provides the second clock tree signal to the other side of the memory.

3. The memory of claim 2, wherein at least part of the circuit is powered down and the second receiver is enabled.

4. The memory of claim 1, wherein the first buffer provides the distributed clock signal to the one side of the memory and the second buffer provides the distributed clock signal to the other side of the memory.

5. The memory of claim 4, wherein the circuit is enabled and the second receiver is powered down.

6. The memory of claim 1, comprising:
first input pads configured to receive the first clock signal on the one side of the memory; and
second input pads configured to receive the second clock signal on the other side of the memory, wherein the first receiver receives the first clock signal via the first input pads and the second receiver receives the second clock signal via the second input pads.

7. The memory of claim 1, wherein the first buffer is situated on the one side of the memory and the second buffer is situated on the other side of the memory.

8. The memory of claim 1, wherein the first buffer selectably provides signals via a metal option.

9. The memory of claim 1, wherein the first buffer selectably provides signals via a transfer gate and fuse option.

10. The memory of claim 1, wherein the first clock signal and the second clock signal are from the same source clock signal.

11. A random access memory comprising:
first data outputs situated on one side of a memory;
second data outputs situated on another side of the memory;
a first receiver situated on the one side of the memory and configured to receive a first clock signal and provide a first clock tree signal;
a second receiver situated on the other side of the memory and configured to receive a second clock signal and provide a second clock tree signal;
distribution circuitry configured to receive the first clock tree signal and provide a single clock signal and to selectively provide one of:
the single clock signal to the first data outputs and the second data outputs; and
the first clock tree signal to the first data outputs and the second clock tree signal to the second data outputs.

12. The random access memory of claim 11, comprising:
a first input pad situated on the one side of the memory and configured to receive the first clock signal;
a second input pad situated on the other side of the memory and configured to receive the second clock signal.

13. The random access memory of claim 11, wherein the first clock signal and the second clock signal are from the same source clock signal.

14. The random access memory of claim 11, wherein the distribution circuitry comprises:
first buffers configured to selectably provide one of the first clock tree signal and the single clock signal to the first data outputs; and
second buffers configured to selectably provide one of the second clock tree signal and the single clock signal to the second data outputs.

15. A memory comprising:
means for providing a first clock tree signal based on a first clock signal and situated on one side of the memory;
means for providing a second clock tree signal based on a second clock signal and situated on another side of the memory;
means for providing a distributed clock signal based on the first clock tree signal;
means for selectably providing one of the first clock tree signal and the distributed clock signal to the one side of the memory; and
means for selectably providing one of the second clock tree signal and the distributed clock signal to the other side of the memory.

16. The memory of claim 15, wherein the means for selectably providing one of the first clock tree signal and the distributed clock signal to the one side of the memory provides the first clock tree signal to the one side of the memory and the means for selectably providing one of the second clock tree signal and the distributed clock signal to the other side of the memory provides the second clock tree signal to the other side of the memory.

17. The memory of claim 16, wherein at least part of the means for providing a distributed clock signal is powered down.

18. The memory of claim 15, wherein the means for selectably providing one of the first clock tree signal and the distributed clock signal to the one side of the memory provides the distributed clock signal to the one side of the memory and the means for selectably providing one of the second clock tree signal and the distributed clock signal to the other side of the memory provides the distributed clock signal to the other side of the memory.

19. The memory of claim 18, wherein the means for providing a second clock tree signal is powered down.

20. The memory of claim 15, comprising:
means for receiving the first clock signal on the one side of the memory; and
means for receiving the second clock signal on the other side of the memory.

21. A method of clocking a memory, comprising:
receiving a first clock signal on one side of the memory;
receiving a second clock signal on another side of the memory;
providing a first clock tree signal based on the first clock signal;
providing a second clock tree signal based on the second clock signal;
providing a distributed clock signal based on the first clock tree signal;
providing a selected one of the first clock tree signal and the distributed clock signal to the one side of the memory; and
providing a selected one of the second clock tree signal and the distributed clock signal to the other side of the memory.

22. The method of claim 21, wherein providing a selected one of the first clock tree signal and the distributed clock signal provides the first clock tree signal to the one side of the memory and providing a selected one of the second clock tree signal and the distributed clock signal provides the second clock tree signal to the other side of the memory.

23. The method of claim 22, comprising:
disabling at least part of providing a distributed clock signal.

24. The method of claim 21, wherein providing a selected one of the first clock tree signal and the distributed clock signal provides the distributed clock signal to the one side of the memory and providing a selected one of the second clock tree signal and the distributed clock signal provides the distributed clock signal to the other side of the memory.

25. The method of claim 24, comprising:
disabling providing a second clock tree signal.

26. A method of clocking a random access memory comprising:
outputting first data on one side of a memory;
outputting second data on another side of the memory;
providing a first clock tree signal based on a first clock signal;
providing a second clock tree signal based on a second clock signal;
providing a single clock signal based on the first clock tree signal;
selecting between available options of:
providing the single clock signal to output the first data on the one side of the memory and to output the second data on the other side of the memory; and
providing the first clock tree signal to output the first data on the one side of the memory and the second clock tree signal to output the second data on the other side of the memory.

27. The method of claim 26, comprising:
receiving the first clock signal on the one side of the memory; and
receiving the second clock signal on the other side of the memory.

28. The method of claim 26, wherein selecting between available options comprises at least one of metalizing paths to select one of the available options and fusing to provide paths via transfer gates to select one of the available options.

29. A system, comprising:
an external circuit; and
a memory configured to transfer data to and receive data from the external circuit, the memory including:
a first receiver situated on one side of the memory and configured to receive a first clock signal and provide a first clock tree signal;
a second receiver situated on another side of the memory and configured to receive a second clock signal and provide a second clock tree signal;
a circuit configured to receive the first clock tree signal and provide a distributed clock signal;
a first buffer configured to selectably provide one of the first clock tree signal and the distributed clock signal to the one side of the memory; and
a second buffer configured to selectably provide one of the second clock tree signal and the distributed clock signal to the other side of the memory.

30. The system of claim 29, wherein the first buffer provides the first clock tree signal to the one side of the memory and the second buffer provides the second clock tree signal to the other side of the memory.

31. The system of claim 29, wherein the first buffer provides the distributed clock signal to the one side of the memory and the second buffer provides the distributed clock signal to the other side of the memory.

32. The system of claim 29, comprising:
first input pads configured to receive the first clock signal on the one side of the memory; and
second input pads configured to receive the second clock signal on the other side of the memory, wherein the first receiver receives the first clock signal via the first input pads and the second receiver receives the second clock signal via the second input pads.
